(19) United States
(12) Patent Application Publication
(10) Pub. No.: US 2008/0152685 A1
(43) Pub. Date: Jun. 26, 2008

(54) PROCESS FOR PRODUCING AN ANTIMICROBIAL COATING

(76) Inventors: Richard I. Blackwell, Webster, NY (US); Scott J. Ingham, Hilton, NY (US); Catherine Scheuer, West Henrietta, NY (US); Joseph C. Salamone, Boca Raton, FL (US)

Correspondence Address: Bausch & Lomb Incorporated, One Bausch & Lomb Place, Rochester, NY, 14604-2701, US

(21) Appl. No.: 11/954,073

(22) Filed: Dec. 11, 2007

Related U.S. Application Data
(60) Provisional application No. 60/870,977, filed on Dec. 20, 2006.

(51) Int. Cl. A01N 25/34; A01N 43/40; A01P 1/00; C23C 14/06

(52) U.S. Cl. 424/412; 424/78.31; 427/569

(57) ABSTRACT

A process for covalently attaching an antimicrobial coating to a polymeric surface. The process comprises contacting the surface of the polymer with a plasma having reactive nitrogen compounds to provide a plasma-treated surface with —NHR groups, wherein R is hydrogen, hydroxyl or C₁₋₂alkyl, reacting the —NHR groups with a surface linking agent, and attaching an amine-containing polymer to the linking agent to form the antimicrobial coating. The surface linking agent is selected from the group consisting of dihaloalkyl, a dihaloalkenyl, and a dihalomethylaryl. The invention is also directed to a contact lens case or a contact lens with an antimicrobial coating.

This application claims priority to U.S. provisional application Ser. No. 60/870,977, filed Dec. 20, 2006, the entire disclosure of which is incorporated herein by reference.

### FIELD OF THE INVENTION

The invention relates to a contact lens or contact lens case with an antimicrobial coating covalently bound to a pre-coated surface of the contact lens or contact lens case. The invention also relates to a process for providing a covalently bound, antimicrobial coating to a contact lens or contact lens case.

### DISCUSSION OF RELATED ART

Contact lenses are a convenient and effective way of correcting vision that has grown in popularity to over 30 million users worldwide. Some contact lenses, including extended wear contact lenses, require routine care including disinfection, cleaning and contact lens conditioning. Disinfection refers to the prevention of infection to the eye of a patient caused by microbes. Cleaning of a contact lens refers to removal of debris, protein or lipids from the surface of a contact lens. Multipurpose solutions such as ReNu® and ReNu® MultiPlus by Bausch & Lomb, Rochester, N.Y., are designed to clean and disinfect contact lenses if used in accordance with a prescribed care regimen. For example, ReNu MultiPlus requires a patient to rinse each side of their contact lenses and soak the contact lens for a minimum of four hours. Patients are also instructed to thoroughly wash their hands with soap just prior to handling the lenses and to use fresh solution each time they clean and disinfect their lenses. The failure of a patient to follow the prescribed care regimen for their contact lenses and to periodically wash or replace the respective contact lens case can lead to a serious eye infection.

In fact, there recently have been reports of serious eye infections associated with contact lens use. In some instances, investigators have linked these infections to the improper maintenance regimen of the contact lens case. For example, improper care of the contact lens case can result in the formation of a biofilm that can provide a favorable nutritive and protective environment for microbes. Consequently, a properly disinfected contact lens that is placed in a contaminated contact lens case can become contaminated. Therefore, it is very important for a patient to follow the prescribed care regimen for both the contact lens case as well as the contact lenses.

U.S. Pat. No. 5,340,583 describes a contact lens case having an antimicrobial component that is non-leachable under normal use conditions and in an amount effective against one or more microorganisms typically associated with contact lens use. The antimicrobial component is a quaternary ammonium containing compound, an amine-containing compound, a peptide-containing compound, or phosphazene-containing compound, each of which is covalently bound within the polymeric material, e.g., by the reaction of silane groups on the antimicrobial component.

European Patent No. 1,182,928 B1 describes a process for producing an antimicrobial coating on a polymer substrate such as a contact lens by immobilizing an antimicrobial polymer on the substrate by plasma treatment. The antimicrobial polymer is preferably a polymer or copolymer comprising polyy(tert-butylaminoethyl methacrylate).

U.S. Published Patent Application No. 2003/0091641 describes a method of providing an antibacterial coating to a contact lens or a contact lens case. The method includes: coating a surface with SiO₂; hydrating a portion of the SiO₂ on the surface to form a plurality of Si—OH groups; converting at least a portion of the plurality of Si—OH groups on the surface to a plurality of Si—O—Si(alkyl)-NH₂ groups via treatment with a tri(alkoxy)Si-(alkyl)-NH₂ reagent; alkylating a portion of the plurality of Si—O—Si(alkyl)-NH₂ groups with a 1,n-dihaloalkane such as 1,4-dibromobutane to give a plurality of Si—O—Si(alkyl)-NH-(alkyl)-halo groups; and treating the plurality of Si—O—Si(alkyl)-NH-(alkyl)-halo groups with a tertiary-amine-containing polymer.

U.S. Published Patent Application No. 2005/0079197 describes a coated biomedical device. The coating includes a polymeric micelle fixed to the surface of the device. The polymeric micelle has either a hydrophilic core and hydrophobic shell, or a hydrophobic core and a hydrophilic shell. The coating is fixed to the surface of the device by initially subjecting the surface to a plasma generated in the presence of a nitrogen compound to provide surface amino groups.

### SUMMARY OF THE INVENTION

The invention is directed to a process for covalently attaching an antimicrobial coating to a polymeric surface. The process comprises contacting the surface of the polymer with a plasma having reactive nitrogen compounds to provide a plasma-treated surface with —NHR groups, wherein R is hydrogen, hydroxyl or C₁₋₂alkyl, reacting the

—NHR groups with a surface linking agent, and attaching an amine-containing polymer to the linking agent to form the antimicrobial coating. The surface linking agent is selected from the group consisting of dihaloalkyl, a dihaloalkenyl, and a dihalomethylaryl.

The invention is also directed to a contact lens case or a contact lens with an antimicrobial coating.

### DETAILED DESCRIPTION OF THE INVENTION

The invention relates a process for providing an antimicrobial coating on a substrate, e.g., the interior surface of a contact lens case. The process includes plasma treating the substrate surface to provide surface —NHR groups. The plasma treated-surface is then reacted with a linking agent followed by reacting the attached linking agent with an amine-containing polymer. The coating process is applicable to a variety of substrates such as a polyolefin, in particular, a polymeric contact lens case.

In one embodiment, the process provides for the covalentl attaching of an antimicrobial coating to a polymeric surface. The surface of the polymer is treated with a plasma having reactive nitrogen compounds to provide a plasma-treated surface with —NHR groups, wherein R is hydrogen, hydroxyl or C₁₋₂alky. The surface —NHR groups are then reacted with a surface linking agent, which provides one or more reactive sites for attaching an amine-containing polymer to form the antimicrobial coating. The surface linking agent is selected from the group consisting of dihaloalkyl, a dihaloalkenyl, and a dihalomethylaryl.

One advantage of the process is that the antimicrobial agent is non-leaching, and therefore, does not require the presence of a liquid medium to be effective. Thus contact lens cases treated by the process provide efficacy against air-borne as well as solvent-borne microbes.

In one embodiment, the polymer surface is treated with a plasma generated in the presence of ammonia. High electrical potential across electrodes used to generate the plasma ionizes the ammonia. As a result, the plasma-treated surface will include —NHR groups, wherein R is hydrogen, hydroxyl or C₁₋₂alkyl, which are susceptible to halo-alkylation. Typical plasma treatment conditions include an ammonia partial pressure of about 0.3 torr (40 Pa), a power level of about 200 watts and a treatment time of about 1 minute.

Once the polymer surface has been plasma treated, the —NHR groups are contacted with a surface linking agent selected from a dihaloalkyl, a dihaloalkenyl, or a dihalomethylaryl. The halogen substituent can be chloro, bromo, iodo or mixtures thereof. In one embodiment, the halogen is iodo and/or bromo for dihaloalkyl compounds and either chloro, bromo, or iodo for dihaloalkenyl or dihalomethylaryl compounds.

In the case, the haloalkylation is carried out with a dihaloalkyl, the dihaloalkyl compound is preferably a is a 1,n-dihaloalkane, wherein n is greater than one, for example an α,ω-dihaloalkane. Suitable dihaloalkyl compounds comprise 1,4-dibromobutane and 1,5-dibromopentane. In the case, the haloalkylation is carried out with a dihaloalkenyl compound, the dihaloalkenyl compound alkene group is preferably positioned adjacent to a terminal halomethyl group. The use of the dihaloalkenyl compound, 1,4-bromo-2-butene, is preferred. In the case, the haloalkylation is carried out with a dihalomethylaryl compound, the dihalomethylaryl compound is preferably

1,4-bis(dichloromethyl)benzene (α,α′-dichloro-p-xylene). The chain length of the hydrocarbon substituent of the dihaloalkyl compound and/or dihaloalkenyl compound can affect the biocidal efficacy of the antimicrobial coating. A similar affect on biocidal efficacy can occur with the amount of aromatic substituents present in the dihalomethylaryl compound.

The haloalkylation reaction is generally carried out in the liquid phase in the presence of a suitable solvent, e.g., such as nitromethane, under reaction conditions favorable to the reaction of the dihaloalkyl, the dihaloalkenyl, or a dihalomethylaryl reacts with the plasma generated, surface —NHR groups. The conditions employed to conduct the haloalkylation reaction are not closely controlled, but in general a suitable temperature is from about 40° C. to about 100° C. for a period of time from about 1 to about 24 hours. One of ordinary skill in the art would know how to optimize the reaction conditions according to the type of surface linking agent used in the process.

Following the haloalkylation step, that attached linking agent surface is contacted with an amine-containing polymer under reaction conditions in which the amine-containing polymer can covalently bond to the linking agent to provide a polymeric species having antimicrobial activity. For example, is possible for the amine-containing polymer to comprise a tertiary or pyridine groups, which then become quaternized. It is believed that the quaternary amine groups are the active antimicrobial sites of the coating. Typically, the amine-containing polymer comprises a tertiary amine-containing polymer, for example a polymer having a weight-average molecular weight of between about 25,000 and 500,000.

In one embodiment, the amine-containing polymer comprises a tertiary amine located on a side chain or a pendent group extending from the backbone of the polymer. In such a case, a suitable polymer comprises a poly(vinylpyridine), for example poly(4-vinylpyridine), poly(2-vinylpyridine), or poly(2-methyl-5-vinylpyridine), with poly(4-vinylpyridine) being preferred. Related polymers such as poly(N-vinylimidazole) or a poly(N-vinyltriazole) can also be employed. Other suitable polymers having pendent tertiary amino groups include poly(3-acrylamidopropyl-N,N-dimethylamine) and poly(2-methacryloyloxyethyl-N,N-dimethylamine).

In another embodiment, the amine-containing polymer comprises a tertiary amine located on an end group of the polymer. In such a case, a suitable polymer comprises a polyguanide, such as poly(hexamethylene biguanide), or an ionene polymer, such as polyquaternium 1, partially or wholly terminated with an amine compound.

The conditions of the reaction between the attached linking agent and the amine-containing polymer are not closely controlled but the reaction is generally carried out in the liquid phase in the presence of a suitable solvent, e.g., nitromethane, at a temperature of about 60° C. to about 100° C. for a period of time from about 1 to about 24 hours.

The antimicrobial coatings produced by the present process are substantially non-leachable. Thus, the antimicrobial agent is such that it does not migrate, for example, from the contact lens case with which it is originally associated, into a liquid contacting the antimicrobial agent under normal use conditions. Such substantially non-leachable antimicrobial agents do not contaminate contact lenses or liquids used to care for contact lenses under normal use conditions.

The invention will now be more particularly described with reference to the following non-limiting Example.

### EXAMPLE

A commercial contact lens case made of polypropylene is subjected to plasma treatment in the presence of ammonia at a partial pressure of 0.3 torr (40 Pa), a power level of 200 watts and a treatment time of 1 minute and is then immersed in a 90:10 by volume solution of nitromethane and 1,4-dibromobutane with 0.1% triethylamine. The solution containing the case is stirred at 60° C. for a period of 5 hours. The case is then rinsed with nitromethane to remove unreacted 1,4-dibromobutane. The presence of bromine on the case surface following the initial treatment is confirmed by X-ray photoelectron spectroscopy (XPS). The bromo-alkylated case is then immersed in a 90:10 by volume solution of nitromethane and 1-bromobutane comprising 10% poly(4-vinylpyridine) having a weight-average molecular weight of 160,000. The solution and case are stirred at 75° C. for a period of 9 hours. The case is rinsed thoroughly with methanol and distilled water and allowed to dry.

The above disclosure is intended to be illustrative and not exhaustive. This description will suggest many variations and alternatives to one of ordinary skill in this art. The various elements described above can be combined or modified for combination as desired. All these alternatives and variations are intended to be included within the scope of the claims where the term “comprising” means “including, but not limited to”.

Further, the particular features presented in the dependent claims can be combined with each other in other manners within the scope of the invention such that the invention should be recognized as also specifically directed to other embodiments having any other possible combination of the features of the dependent claims. For instance, for purposes of claim publication, any dependent claim which follows should be taken as alternatively written in a multiple dependent form from all prior claims which possess all antecedents referenced in such dependent claim if such multiple dependent format is an accepted format within the jurisdiction (e.g. each claim depending directly from claim 1 should be alternatively taken as depending from all previous claims). In jurisdictions where multiple dependent claim formats are restricted, the following dependent claims should each be also taken as alternatively written in each singly dependent claim format which creates a dependency from a prior antecedent-possessing claim other than the specific claim listed in such dependent claim below.

Lastly, those skilled in the art may recognize other equivalents to the specific embodiment described herein which equivalents are intended to be encompassed by the claims attached hereto.

We claim:

1. A process for covalently attaching an antimicrobial coating to a polymeric surface, the process comprising:
contacting the surface of the polymer with a plasma having reactive nitrogen compounds to provide a plasma-treated surface with —NHR groups, wherein R is hydrogen, hydroxyl or C₁₋₂alkyl;
reacting the —NHR groups with a surface linking agent selected from the group consisting of dihaloalkyl, a dihaloalkenyl, and a dihalomethylaryl, and
attaching an amine-containing polymer to the linking agent to form the antimicrobial coating.

2. The process of claim 1 wherein the plasma is generated in the presence of ammonia.

3. The process of claim 1 wherein the surface linking agent is a dihaloalkyl.

4. The process of claim 1 wherein the surface linking agent is an α,ω-dihaloalkane or an α,ω-dihalo-2-alkene.

5. The process of claim 4 wherein the α,ω-dihaloalkane is 1,4-dibromobutane and the α,ω-dihalo-2-alkene is 1,4-bromo-2-butene.

6. The process of claim 1 wherein the surface linking agent is a dihalomethylaryl compound.

7. The process of claim 6 wherein the dihalomethylaryl compound is 1,4-bis(dichloromethyl)benzene.

8. The process of claim 1 wherein the antimicrobial, amine-containing polymer comprises an amine selected from the group consisting of a tertiary amine group and a pyridine group.

9. The process of claim 1 wherein the antimicrobial, amine-containing polymer comprises poly(4-vinylpyridine).

10. The process of claim 1 wherein the polymer surface is the surface of a contact lens case.

11. The process of claim 1 wherein the polymer surface is the surface of a contact lens.

12. A process of attaching an antimicrobial coating to an interior surface of a contact lens case, the process comprising:
providing a contact lens case with an exposed interior surface;
contacting the interior surface of the lens case with a plasma having reactive nitrogen compounds to provide a plasma-treated surface with —NHR groups, wherein R is hydrogen, hydroxyl or C₁₋₂alkyl;
reacting the —NHR groups with a surface linking agent selected from the group consisting of dihaloalkyl, a dihaloalkenyl, and a dihalomethylaryl, and
attaching an amine-containing polymer to the linking agent to form the antimicrobial coating on the interior surface of the lens case.

13. The process of claim 12 wherein the antimicrobial, amine-containing polymer comprises an amine selected from the group consisting of a tertiary amine group and a pyridine group.

14. The process of claim 12 wherein the antimicrobial, amine-containing polymer comprises poly(4-vinylpyridine).

15. A contact lens case comprising an antimicrobial coating wherein the antimicrobial coating is prepared by a process comprising:
providing a contact lens case with an exposed interior surface;
contacting the interior surface of the lens case with a plasma having reactive nitrogen compounds to provide a plasma-treated surface with —NHR groups, wherein R is hydrogen, hydroxyl or C₁₋₂alkyl;
reacting the —NHR groups with a surface linking agent selected from the group consisting of dihaloalkyl, a dihaloalkenyl, and a dihalomethylaryl, and
attaching an amine-containing polymer to the linking agent to form the antimicrobial coating on the interior surface of the lens case.

16. The process of claim 15 wherein the antimicrobial, amine-containing polymer comprises an amine selected from the group consisting of a tertiary amine group and a pyridine group.

17. The process of claim 15 wherein the antimicrobial, amine-containing polymer comprises poly(4-vinylpyridine).

18. The process of claim 15 wherein the contact lens case comprises polypropylene.
